(19) United States
(12) Patent Application Publication
(10) Pub. No.: US 2025/0125286 A1
(43) Pub. Date: Apr. 17, 2025

(54) SEMICONDUCTOR DEVICE

(71) Applicant: Sumitomo Electric Device Innovations, Inc., Yokohama-shi, Kanagawa (JP)

(72) Inventor: James WONG, Surrey (GB)

(73) Assignee: Sumitomo Electric Device Innovations, Inc., Yokohama-shi, Kanagawa (JP)

(21) Appl. No.: 18/695,467

(22) PCT Filed: Sep. 28, 2021
(86) PCT No.: PCT/JP2021/035721

§ 371 Date: Mar. 26, 2024

(51) Int. Cl. H01L 23/64; H01L 23/043; H01L 23/08; H01L 25/18

(52) U.S. Cl. CPC H01L 23/642; H01L 23/043; H01L 23/08; H01L 25/18

(57) ABSTRACT

A semiconductor device includes a metal base, a wall, a lid, a semiconductor die, and at least one capacitor. The wall is placed on the metal base, and provides an opening portion inside of the wall. The lid is placed on the wall. The semiconductor die is placed on the metal base. The semiconductor die is surrounded with the wall to be placed in the opening portion. The capacitor is placed on the wall. A first end of the capacitor is electrically connected to the semiconductor die, and a second end of the capacitor is electrically connected to the metal base.

### TECHNICAL FIELD

The present disclosure relates to a semiconductor device.

### BACKGROUND ART

Existing transistor devices for cellular infrastructures such as Laterally Diffused Metal Oxide Semi-conductor (LDMOS) or Gallium Nitride (GaN) have experienced increasing demands for higher operational powers as well as operating bandwidths. As a result of both requirements, it becomes necessary to increase the size of transistor packaging to accommodate the power demands.

US2006/0138654 discloses one example of semiconductor devices, which has improved a heat dissipation property of a package for containing semiconductor dies. Semiconductor devices used in microwave frequency are constructed as such, for example, semiconductor dies for amplifying radio frequency signals and various circuit boards connected with the semiconductor dies are arranged in a package. The package is composed of, a bottom plate for fixing semiconductor dies and circuit boards, a wall placed on the periphery of the bottom plate to surround the semiconductor dies and circuit boards, and a lid for covering upper opening formed by the wall.

### CITATION LIST

### Patent Literature

Patent Literature 1: US2006/0138654

### SUMMARY OF INVENTION

The present disclosure provides a semiconductor device. The semiconductor device includes a metal base, a wall, a lid, a semiconductor die, and at least one capacitor. The wall is placed on the metal base and provides an opening portion inside of the wall. The lid is placed on the wall. The semiconductor die is placed on the metal base. The semiconductor die is surrounded with the wall to be placed in the opening portion. The capacitor is placed on the wall. A first end of the capacitor is electrically connected to the semiconductor die, and a second end of the capacitor is electrically connected to the metal base.

### BRIEF DESCRIPTION OF DRAWINGS

FIG. 1 is a plan view of showing a structure of a semiconductor device according to a first embodiment of the present disclosure.

FIG. 2 is a cross sectional view of the semiconductor device along a line II-II shown in FIG. 1.

FIG. 3 is an enlarged plan view of showing a connecting structure of a first capacitor of the semiconductor device shown in FIG. 1.

FIG. 4 is a cross sectional view of the connecting structure of the first capacitor along a line IV-IV shown in FIG. 3.

FIG. 5 is a perspective view of showing a structure of a semiconductor device according to a modified example of the first embodiment of the present disclosure.

FIG. 6 is an enlarged perspective view of a connecting structure of a capacitor and a semiconductor die of the semiconductor device shown in FIG. 5.

FIG. 7 is a perspective view of showing the semiconductor device shown in FIG. 6 with a lid.

FIG. 8 is a perspective view of showing a structure of a semiconductor device according to a second embodiment of the present disclosure.

FIG. 9 is a perspective view of showing a structure of the semiconductor device shown in FIG. 8 with lids.

FIG. 10 is a plan view of showing a structure of a semiconductor device of a comparative example.

FIG. 11 is a cross sectional view of the semiconductor device shown in FIG. 10 along an XI-XI line.

### DESCRIPTION OF EMBODIMENTS

### Problem to be Solved by the Present Disclosure

In order to enable better compatibility for supporting wider-bandwidths, external Video Bandwidth (VBW) leads have been introduced on packages, such as the package described in Patent literature 1. Previously, the core package has always been ceramic and only single layered. The dielectric of ceramic is high and therefore any top metallization artwork will have an immediate impact (negative impact in this instance). This current approach has not been adopted previously due to the technology of printed circuit boards.

### Advantageous Effects of the Present Disclosure

According to the present disclosure, the amount of inductance that will eventually form as a series LC resonance can be reduced.

### Description of Embodiments of the Present Disclosure

Embodiments of the present disclosure will be enumerated and described. According to an aspect of the present disclosure, there is provision of a semiconductor device including a metal base, a wall, a lid, a semiconductor die, and at least one capacitor. The wall is placed on the metal base and provides an opening portion inside of the wall. The lid is placed on the wall. The semiconductor die is placed on the metal base. The semiconductor die is surrounded with the wall to be placed in the opening portion. The capacitor is placed on the wall. A first end of the capacitor is electrically connected to the semiconductor die, and a second end of the capacitor is electrically connected to the metal base.

The above semiconductor device places the capacitor on the wall, and a first end of the capacitor is electrically connected to the semiconductor die and a second end of the capacitor is electrically connected to the metal base. Accordingly, this embodiment reduces the length of wire-bond connecting the semiconductor die and the capacitor. Thus, this embodiment reduces the amount of inductance that will eventually form as a series LC resonance. In addition, in this embodiment, the characteristic of the capacitor is not influenced. Thus, circuit performance of the semiconductor device can be improved.

As one embodiment, the semiconductor device may further include a first upper pattern placed on the wall and a second upper pattern placed on the wall. The first upper pattern may electrically connect the first end of the capacitor with the semiconductor die. The second upper pattern may electrically connect the second end of the capacitor with the metal base. In this embodiment, the wall may have a protruding part inside the wall. The first upper pattern may include a region provided on the protruding part of the wall, and the region of the first upper pattern may be electrically connected to a drain pad of the semiconductor die by a wiring. This embodiment further reduces the length of the wire-bond connecting the semiconductor die with the capacitor. Thus, this embodiment further reduces the amount of the inductance that will eventually form as a series LC resonance and improve the circuit performance of the semiconductor device.

As one embodiment, the semiconductor device may further include a third upper pattern and a fourth upper pattern each placed on the wall. The third upper pattern may be electrically connected to the first upper pattern. The fourth upper pattern may be electrically connected to the second upper pattern and may be electrically connected to the metal base via a via-hole.

As one embodiment, the semiconductor device may further include a frame placed on the wall. The frame may include a first upper pattern, a first lower pattern, and a dielectric sandwiched between the first upper pattern and the first lower pattern. In this embodiment, the first upper pattern may be electrically connected to the first end of the capacitor by a solder or electroconductive adhesive. The solder may be made of Gold-tin (AuSn) alloy solder paste, or Silver solder paste. The electroconductive adhesive may be made of a silver loaded epoxy, a low temperature indium film. The first lower pattern may be electrically connected to the first upper pattern by a first via-hole through the dielectric and may be electrically connected to the semiconductor die by a wiring.

In the above embodiment, the frame may further include a second upper pattern and a second lower pattern. The second upper pattern and the second lower pattern may sandwich the dielectric therebetween. In this semiconductor device, the second upper pattern may be electrically connected to the second end of the capacitor by a solder or electroconductive adhesive, and the second lower pattern may be electrically connected to the second upper pattern by a second via-hole through the dielectric and may be connected to the metal base. The solder may be made of Gold-tin (AuSn) alloy solder paste, or Silver solder paste. The electroconductive adhesive may be made of a silver loaded epoxy, a low temperature indium film.

As one embodiment, the metal base may be made of a high thermal conductivity material of 50 W/(m·K) or more, which can be copper, or a copper alloy, and the wall may be made of a glass-microfiber-reinforced resin or a fluorocarbon resin.

As one embodiment, the semiconductor die may include a substrate and a nitride semiconductor layer disposed on a surface of the substrate.

As one embodiment, the semiconductor device may further include an impedance matching circuit placed on the metal base. The impedance matching circuit may be surrounded with the wall and connected to the semiconductor die. In this semiconductor device, the lid may cover the semiconductor die and the impedance matching circuit.

As one embodiment, the at least one capacitor may include a first capacitor and a second capacitor. In this semiconductor device, the first capacitor may be placed on a first side portion of the wall, and the second capacitor may be placed on a second side portion of the wall, opposite to the first side portion.

As one embodiment, the lid may cover the capacitor on the wall.

As one embodiment, the semiconductor die may include a first semiconductor die and a second semiconductor die, and the opening portion may include a first opening portion and a second opening portion. In this semiconductor device, the first semiconductor die may be placed inside the first opening and the second semiconductor die may be placed inside the second opening.

As one embodiment, the semiconductor device may further include a first impedance matching circuit and a second impedance matching circuit. The lid may include a first lid and a second lid. In this semiconductor device, the first lid may cover the first semiconductor die and the first impedance matching circuit which are placed inside the first opening, and the second lid may cover the second semiconductor die and the second impedance matching circuit which are placed inside the first opening.

As one embodiment, the lid may include a first lid and a second lid, and the at least one capacitor may include a first capacitor, a second capacitor, a third capacitor and a fourth capacitor. In this semiconductor device, the first lid may cover the first capacitor and the second capacitor, and the second lid may cover the third capacitor and the fourth capacitor.

As one embodiment, the semiconductor device may further include a first impedance matching circuit and a second impedance matching circuit. In the semiconductor device, the lid may cover the first semiconductor die, the second semiconductor die, the first impedance matching circuit, and the second impedance matching circuit.

As one embodiment, the at least one capacitor may include a first capacitor and a second capacitor each placed on the wall. The lid may cover the first capacitor and the second capacitor.

### Details of Embodiments of the Present Disclosure

Specific examples of a semiconductor device of the present disclosure will be described below with reference to the drawings. The present invention is not limited to these examples, and is indicated by the scope of the claims and is intended to include meanings equivalent to the scope of the claims and all modifications within the scope of the claims. In the following description, the same components in descriptions of the drawings are denoted with the same reference numerals, and redundant descriptions will be omitted.

### First Embodiment

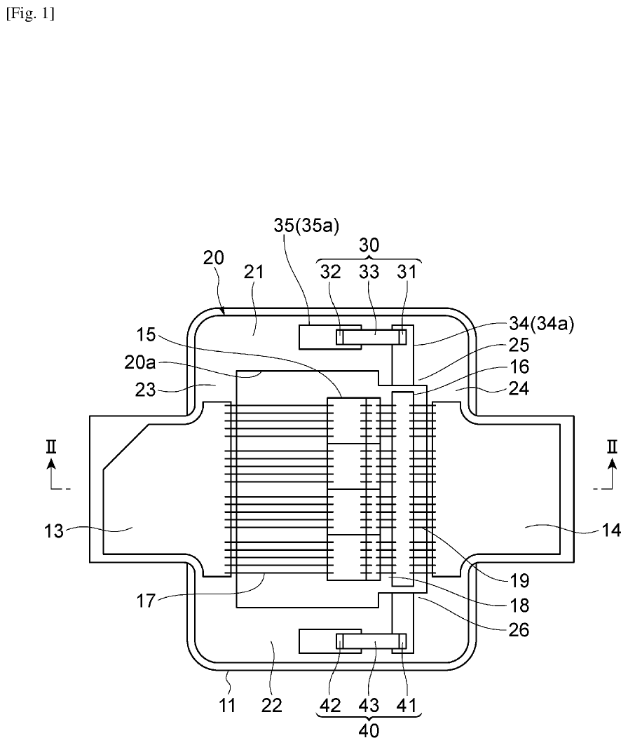

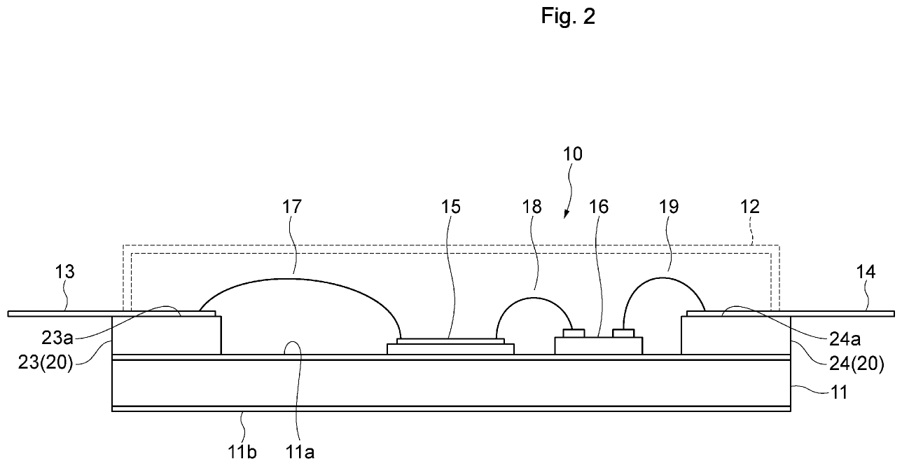

FIG. 1 is a plan view of showing a structure of a semiconductor device according to a first embodiment of the present disclosure. FIG. 2 is a cross sectional view of the semiconductor device along a line II-II shown in FIG. 1. As shown in FIGS. 1 and 2, a semiconductor device 10, which has a package for containing a semiconductor die, includes a metal base 11, a lid 12, a first lead 13, a second lead 14, an impedance matching circuit 15, a semiconductor die 16, a wall 20, a first capacitor 30, and a second capacitor 40.

The metal base 11 has a rectangular plane shape and made of meal such as a copper or a copper alloy. The metal base 11 may be made of a high thermal conductivity material of 50 W/(m·K) or more. The metal base 11 may have a thickness equal to 1.05 mm or thicker. The metal base 11 includes an upper surface 11a and a back pattern 11b.

The wall 20 is a substantially rectangular frame-shaped member made of a dielectric material such as a resin and is placed on the metal base 11. The wall 20 provides an opening portion 20a on the inside of the wall 20. The wall 20 includes a first side portion 21, a second side portion 22, a third side portion 23, and a fourth side portion 24. The first side portion 21 faces the second side portion 22, and the third side portion 23 faces the fourth side portion 24. The impedance matching circuit 15 and the semiconductor die 16 are disposed within the opening portion 20a defined by the first to fourth side portions 21 to 24. The first side portion 21 further includes a protruding part 25 extending toward the semiconductor die 16, and the second portion 22 further includes a protruding part 26 extending toward the semiconductor die 16. The wall 20, for example, may be made of a glass-microfiber-reinforced resin, a fluorocarbon resin or the like.

The lid 12 is placed on the wall 20 to cover the impedance matching circuit 15 and the semiconductor die 16. The lid 12 is made of a metal, such as aluminum oxide (AlO). The lid 12 may cover the first capacitor 30 and the second capacitor 40 together with the impedance matching circuit 15 and the semiconductor die 16.

The first lead 13 and the second lead 14 are plate-shaped members made of a metal, and may be a thin metal plate made of, for example, copper, a copper alloy, or an iron alloy. One end of the first lead 13 is joined to an upper surface 23a of the third side portion 23 of the wall 20. The first lead 13 is insulated from the main surface 11a of the metal base 11 by the third side portion 23 of the wall 20. One end of the second lead 14 is joined to the upper surface 24a of the fourth side portion 24 of the wall 20. The second lead 14 is insulated from the main surface 11a of the metal base 11 by the fourth side portion 24 of the metal wall 20.

The impedance matching circuit 15 matches impedance between the first lead 13 and the semiconductor die 16. One end of the impedance matching circuit 15 is electrically connected to the first lead 13 via bonding wires 17. The other end of the impedance matching circuit 15 is electrically connected to gate electrodes of the semiconductor die 16 via bonding wires 18. In this way, the first lead 13 is electrically connected to the gate electrodes of the semiconductor die 16 through the impedance matching circuit 15. The impedance matching circuit 15 is placed on the surface 11a of the metal base 11 and fixed to the metal base 11 by an adhesive.

The semiconductor die 16 is a transistor to amplify radio frequency signals. The semiconductor die 16 may be, for example, a transistor including a substrate and a nitride semiconductor layer which is a layer epitaxially grown for from a surface of the substrate. An example of the substrate includes a Si substrate, or a SiC substrate. The nitride semiconductor layer is, for example, a GaN layer. The semiconductor die 16 is placed on the surface 11a of the metal base 11 and fixed to the metal base 11 by an adhesive. The semiconductor die 16 is surrounded with the wall 20 so as to be placed in the opening portion 20a. The gate electrodes of the semiconductor die 16 are connected to the impedance matching circuit 15 and source electrodes of the semiconductor die 16 are connected to the second lead 14. Drain electrodes of the semiconductor die 16 are connected to the first capacitor 30 and the second capacitor 40.

The first capacitor 30 includes a first electrode 31, a second electrode 32, and a dielectric 33. The dielectric 33 is made of ceramics and is sandwiched between the first electrode 31 and the second electrode 32. The first electrode 31 is connected to the semiconductor die 16 and the second electrode 32 is connected to the metal base 11 to be grounded. The first capacitor 30 is placed on the first side portion 21 of the wall 20. The second capacitor 40 includes a first electrode 41, a second electrode 42, and a dielectric 43. The dielectric 43 is made of ceramics and is sandwiched between the first electrode 41 and the second electrode 42. The first electrode 41 is connected to the semiconductor die 16 and the second electrode 42 is connected to the metal base 11 to be grounded. The second capacitor 40 is placed on the second side portion 22 of the wall 20. Each of the first capacitor 30 and the second capacitor 40 can be a chip capacitor instead of a vertically mounted capacitor of a comparative example described later. Each of the first capacitor 30 and the second capacitor 40 may be a surface mount device (SMD) ceramic capacitor having a 0805 (2012 metric) size or a smaller size.

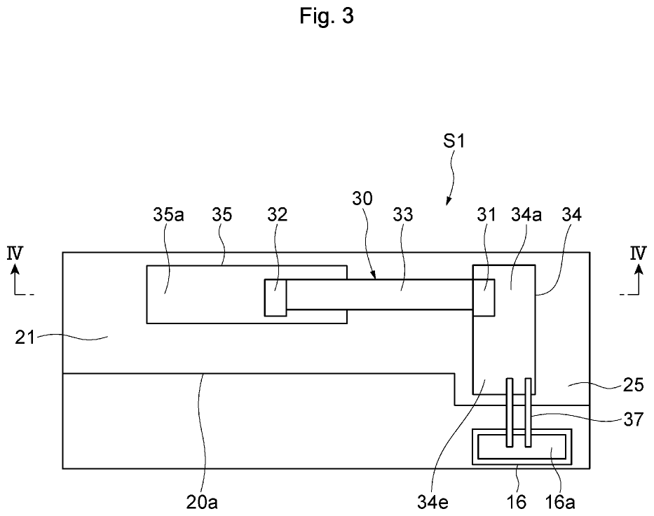

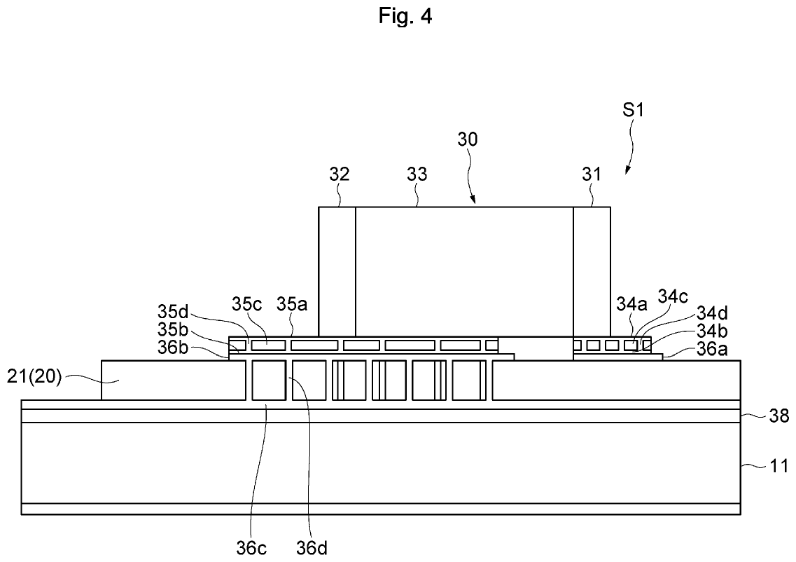

Next, details of a connecting structure of the first capacitor 30 will be described by referring to FIG. 3 and FIG. 4. A connecting structure of the second capacitor 40 has a similar structure with the connecting structure of the first capacitor 30 and thus, redundant descriptions thereof will be omitted. FIG. 3 is an enlarged plan view of showing a connecting structure of the first capacitor 30 of the semiconductor device 10. FIG. 4 is a cross sectional view of the connecting structure of the first capacitor 30 along a line IV-IV in FIG. 3. As shown in FIGS. 3 and 4, in the connecting structure S1, a first board 34 and a second board 35 are provided on the first side portion 21 of the wall 20. The first board 34 and the second board 35 are isolated from each other.

The first board 34 includes a first upper pattern 34a, a first lower pattern 34b, and a first dielectric 34c. The first upper pattern 34a is provided on an upper surface of the first dielectric 34c, and the first lower pattern 34b is provided on a lower surface of the first dielectric 34c. Signal vias 34d are provided within the first dielectric 34c to pass through the first dielectric 34c and electrically connect the first upper pattern 34a with the first lower pattern 34b. The first upper pattern 34a is a single layer and is electrically connected to the first electrode 31 of the first capacitor 30 by a solder or electroconductive adhesive. The first lower pattern 34b is attached to a third upper pattern 36a placed on an upper surface 21a of the first side portion 21 by a solder or electroconductive adhesive. The first upper pattern 34a, the first lower pattern 34b, and the third upper pattern 36a are made of a copper, a gold or the like. The above solder may be made of Gold-tin (AuSn) alloy solder paste, or Silver solder paste. The above electroconductive adhesive may be made of a silver loaded epoxy, a low temperature indium film.

The second board 35 includes a second upper pattern 35a, a second lower pattern 35b, and a second dielectric 35c. The second upper pattern 35a is provided on an upper surface of the second dielectric 35c and the second lower pattern 35b is provided on a lower surface of the second dielectric 35c. Vias 35d are provided within the second dielectric 35c to pass through the second dielectric 35c and connect the second upper pattern 35a with the second lower pattern 35b. The second upper pattern 35a is connected to the second electrode 32 of the first capacitor 30 by a solder or electroconductive adhesive. The second lower pattern 35b is attached to a fourth upper pattern 36b placed on an upper surface 21a of the first side portion 21 by a soldering or electroconductive adhesive. The fourth upper pattern 36b is connected to a third lower pattern 36c placed on a lower surface 21b of the first side portion 21 of the wall 20 by vias 36d. The lower surface 21b, where the third lower pattern 36c is placed, is attached to the metal base 11 with a conductive adhesive film 38, which is a thermally and electrically conductive film. The second upper pattern 35a, the second lower pattern 35b, the fourth upper pattern 36b, and the third lower pattern 36c are made of a copper, a gold or the like.

In the above described connecting structure S1, the first capacitor 30 and the first upper pattern 34a are arranged close to the semiconductor die 16 because the first capacitor 30 is located on the wall 20. Further, the first upper pattern 34a has a region 34e provided on the protruding part 25 of the wall 20, which is closer to the semiconductor die 16. The region 34e is connected to a drain pad 16a extending a drain electrode of the semiconductor die 16 by wirings 37. Accordingly, a length of the wirings 37 connected between the first upper pattern 34a (the region 34e) and the drain pad 16a extending the drain electrode of the semiconductor die 16 is shorter than a length of a wring which is directly connected between the drain electrode of the semiconductor die 16 and the first electrode 31 of the first capacitor 30. The first upper pattern 34a is close to the electrode of the semiconductor die 16 than the second upper pattern 35a. The second upper pattern 35a is electrically connected to the metal base 11 of the package by via holes 35d and via holes 36d.

In this semiconductor device 10, the VBW signal is connected to an edge of the first capacitor 30 and/or an edge of the second capacitor 40 by means of wire-bonds from the drain terminals of the active transistor die (the semiconductor die 16), and the other end of the first capacitor 30 and/or the other end of the second capacitor 40 is grounded. Thus, these capacitors can act as a short-circuit to these VBW frequencies.

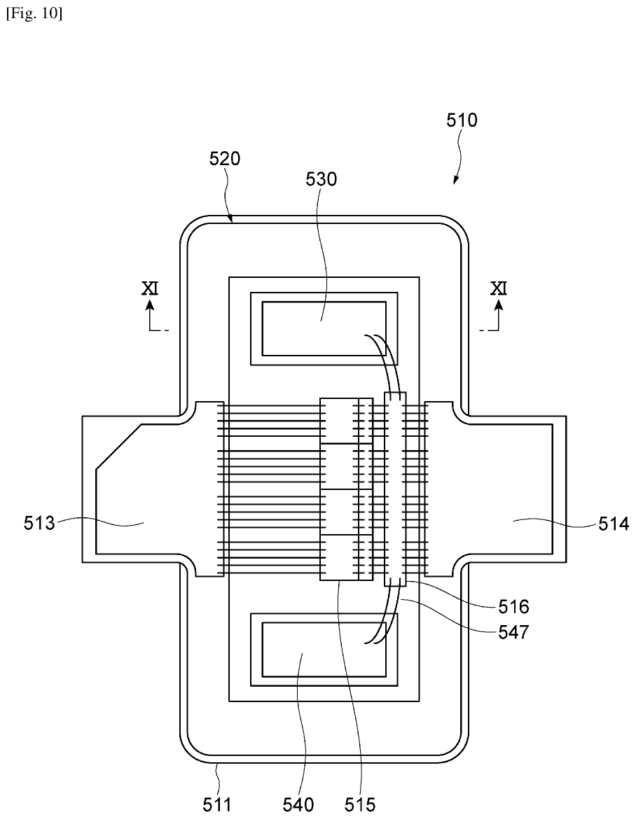

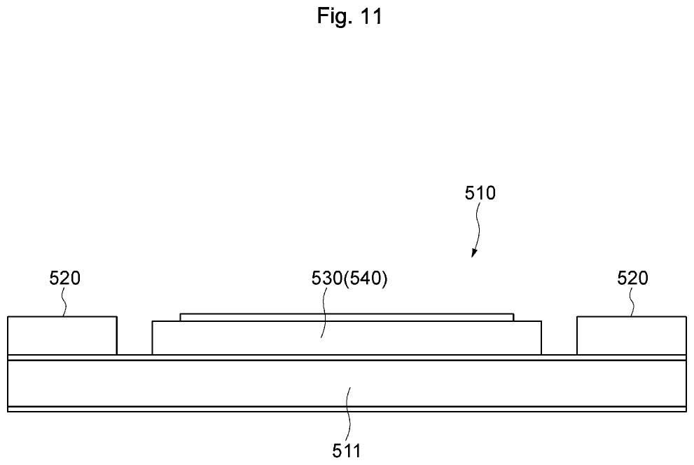

Advantageous effects obtained by the semiconductor device 10 of the present embodiment having the above-described configurations will be described in contrast to a comparative example shown in FIG. 10 and FIG. 11. FIG. 10 is a plan view of showing a structure of a semiconductor device of a comparative example. FIG. 11 is a cross sectional view of the semiconductor device shown in FIG. 10 along an XI-XI line. As shown in FIGS. 10 and 11, a semiconductor device 510 according to the comparative example includes a metal base 511, a lid, a first lead 513, a second lead 514, an impedance matching circuit 515, a semiconductor die 516, a wall 520, a first capacitor 530, and a second capacitor 540. Each of the first capacitor 530 and the second capacitor 540 is a vertical capacitor, which includes an upper electrode, a lower electrode, and dielectric between the upper electrode and the lower electrode. The first capacitor 530 and the second capacitor 540 are placed on the metal base 511 and are located inside the wall 520. In the semiconductor device 510, the first capacitor 530 and the second capacitor 540 are connected to the semiconductor die 516 by wirings 537 and wirings 547, respectively. The wirings 537 and the wirings 547 are longer that the wirings 37 and wirings 47 of the semiconductor device 10.

In the above embodiment, the length of the wire-bonds is significantly reduced comparing to the comparative example, therefore this embodiment can reduce the amount of inductance that will eventually form as a series LC resonance. In addition, the characteristics of the capacitor will not be influenced in this embodiment and therefore circuit performance of the semiconductor device 10 will be improved. The external VBW functionality allows a large surface mount capacitor, such as 1 μF or more rated at 100V.

In the present embodiment, the following benefits can be obtained further, comparing the comparative example. First, smaller compact design foot-print of the power amplifier layout can be obtained. This is mostly due to the lead width dimension. This embodiment is more than half the size of the lead width. Secondly, this embodiment allows a wider isolation path between the primary leads to reduce interference. Thirdly, this embodiment has no requirements for an external VBW lead meant that the power amplifier artwork/layout can be kept smaller. Fourthly, this embodiment can provide with up to 8 primary leads possible, maximum available power output is thereby increased. Finally, this embodiment can provide that required terminations for video frequencies (<1 GHz) which is often done internally. In the comparative example, direct wire-bonding to a vertically mounted capacitor will require fairly long wire-bonds and therefore is not easily feasible. But this embodiment can shorten the length of the wire-bonds and therefore is easily feasible.

### Modified Example of the First Embodiment

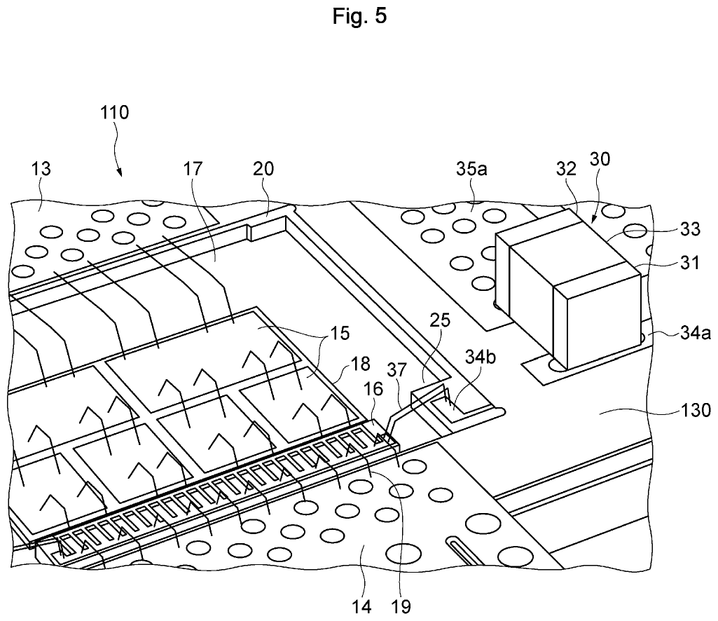

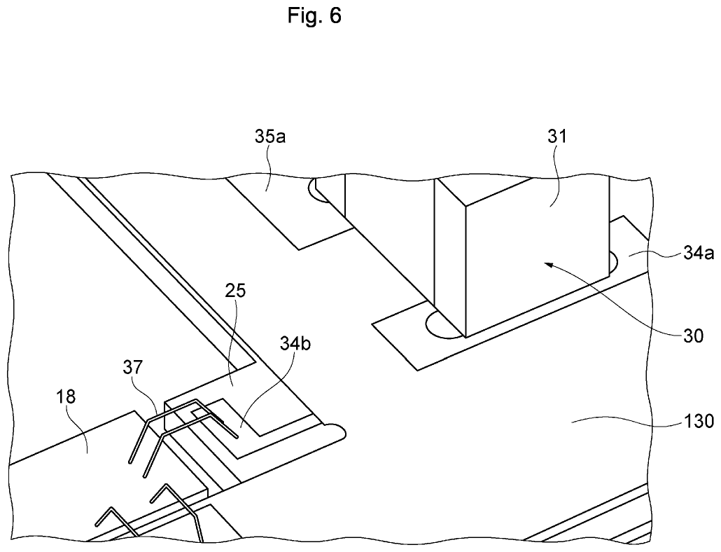

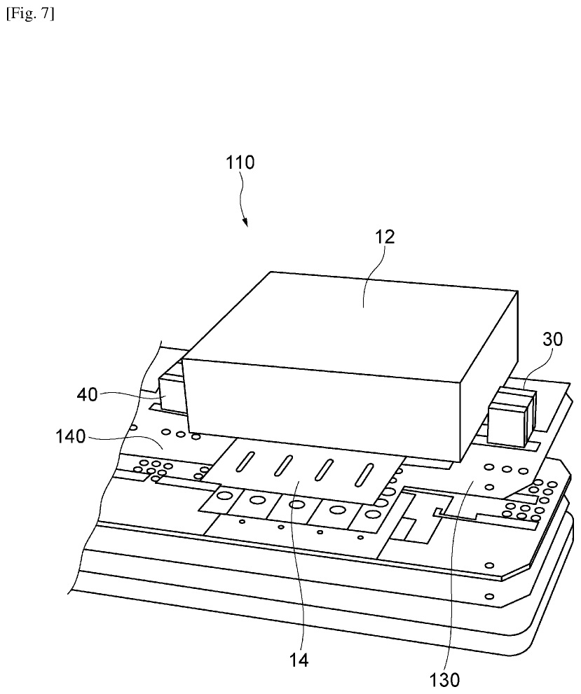

Next, a modified example of the first embodiment of the present disclosure will be described by referring to FIG. 5, FIG. 6 and FIG. 7. FIG. 5 is a perspective view of showing a structure of a semiconductor device according to a modified example of the first embodiment of the present disclosure. FIG. 6 is an enlarged perspective view of a connecting structure of a capacitor and a semiconductor die of the semiconductor device shown in FIG. 5. FIG. 7 is a perspective view of showing the semiconductor device shown in FIG. 5 with a lid. As illustrated in FIGS. 5 to 7, a semiconductor device 110 of the modified example, includes a metal base 11, a lid 12, a first lead 13, a second lead 14, an impedance matching circuit 15, a semiconductor die 16, a wall 20, a first capacitor 30, and a second capacitor 40. The impedance matching circuit 15 is made of a ceramic, such as an aluminum oxide, an aluminum nitride, or the like.

The semiconductor device 110 further includes a frame 130 and a frame 140, instead of the first dielectric 34c of the first board 34 and the second dielectric 35c of the second board 35. The frame 130 and the frame 140 are made of a low loss dielectric composite material (e.g. glass microfiber reins and alike). The frame 130 is provided composing common the first dielectric 34c of the first board 34 and the second dielectric 35c of the second board 35. The first upper pattern 34a and the second upper pattern 35a are placed on an upper surface of the frame 130. The frame 130 is provided over the entire surface of the first side portion 21 of the wall 20. A frame 140 is also provided over the entire surface of the second side portion 22 of the wall, on which the second capacitor 40 is placed. The frame 140 has a same function of the ferrule 130. The frame 130 and the frame 140 can be composed of one frame.

In this modified example, a tip part of the first lower pattern 34b is provided on the protruding part 25 of wall 20. A length of the wirings 37 connected between the first lower pattern 34b and the portion extending the drain electrode of the semiconductor die 16 is shorter than a length of a wring which is directly connected between the drain electrode of the semiconductor die 16 and the first electrode 31 of the first capacitor 30. The first lower pattern 34b is close to the electrode of the semiconductor die 16 than the first upper pattern 34a. In this modified example, the first upper pattern 34a is not provided on the protruding part 25 of wall 20. Thus, the solder for mounting the first capacitor 30 on the first upper pattern 34a is prevented from entering the inside of the package by the first upper pattern 34a not extending side the semiconductor die 16.

As shown in FIG. 7, the semiconductor device 110 has a lid 12 which is placed on the wall 20 of the package. The lid 12 covers the impedance matching circuit 15 and the semiconductor die 16 surrounded by the wall 20. The lid 12 is contact to a portion of the frame 130. In some example, the lid 12 may cover impedance matching circuit 15 and the semiconductor die 16 surrounded by the wall 20, and may further cover the first capacitor 30 and the second capacitor 40 both provided on the wall 20. In this embodiment, the lid 12 is contact to a portion of the frame 130.

### Second Embodiment

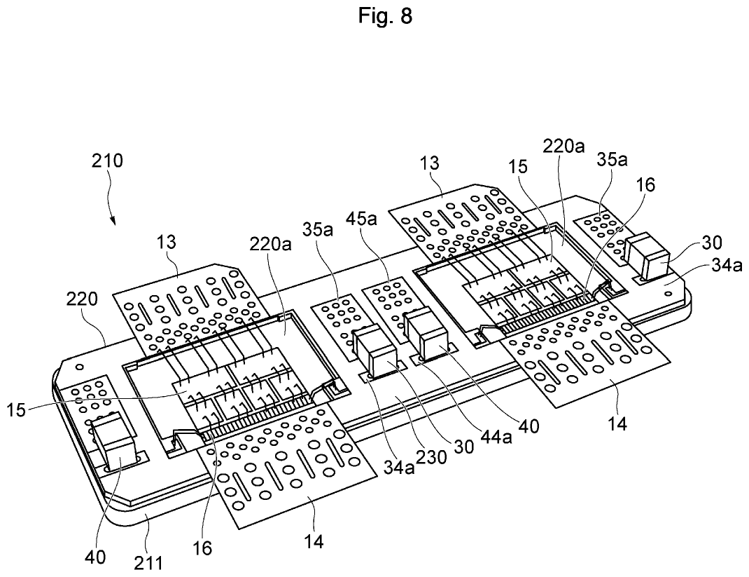

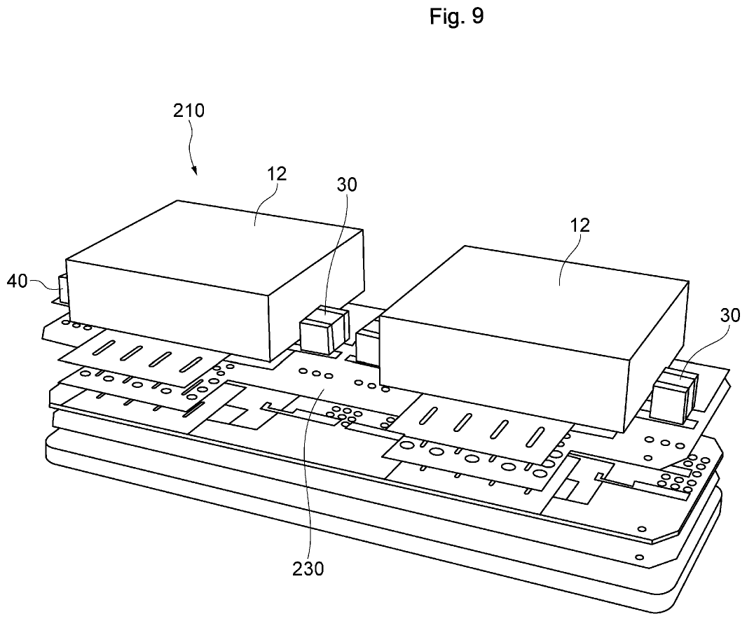

Next, a second embodiment of the present disclosure will be described by referring to FIG. 8 and FIG. 9. FIG. 8 is a perspective view of showing a structure of a semiconductor device according to a second embodiment of the present disclosure. FIG. 9 is a perspective view of showing a structure of the semiconductor device shown in FIG. 8 with lids. As shown in FIGS. 8 and 9, a semiconductor device 210 includes a metal base 211, lids 12, first leads 13, second leads 14, impedance matching circuits 15, semiconductor dies 16, a wall 220, first capacitors 30, and second capacitors 40. Connecting structures of the first capacitors 30 and connecting structures of the second capacitors 40 of the semiconductor device 210 in this embodiment have similar structures with the connecting structures of the first capacitor 30 and the second capacitor 40 of the semiconductor device 10 or 110, and thus, redundant descriptions thereof will be omitted. In the following description, different points of the second embodiment from the first embodiment are mainly explained.

The wall 220 provides a plurality of opening portion 220a inside the wall 220, for example two opening portions 220a in the drawings. The semiconductor device 210 provides the impedance matching circuits 15 and the semiconductor dies 16 inside the opening portions 220a, respectively, as shown in FIG. 8. The semiconductor device 210 also provides a pair of the first capacitor 30 and the second capacitor 40 for each of semiconductor dies 16 provided on the opening portions 220a. In this embodiment, the first capacitors 30 and the second capacitors 40 are placed on the wall 220 through one common frame 230.

The semiconductor device 210 includes a plurality of lids 12 provided on the wall 220 of the package. Each of the lids 12 covers the semiconductor die 16 and the impedance matching circuit 15, that surrounded by the wall 220. The lids 12 are contact to a portion of the frame 230. As another example, the lid 12 may cover the semiconductor dies 16 and the impedance matching circuits 15 surrounded by the wall 220. The lid is contact to a portion of the frame 230. Then, the lid 12 may covers the first capacitors 30 and the second capacitor 40 provided on the wall 220.

Hereinabove, the semiconductor devices according to the present embodiments have been described, but the present invention is not limited thereto and various modifications can be applied.

### REFERENCE SIGNS LIST

10, 110, 210 Semiconductor Device
11, 211 Metal Base
12 Lid
13 Input Lead
14 Output Lead
15 Impedance Matching Circuit
16 Semiconductor Die
16a Drain pad
17, 18, 19 Wiring
20, 220 Wall
21 First Side Portion
22 Second Side Portion
23 Third Side Portion
24 Fourth Side Portion
25, 26 Protruding Part
30 First Capacitor
31, 41 First Electrode
32, 42 Second Electrode
33, 43 Dielectric
34 First Board
34a First Upper Pattern
34b First Lower Pattern
34c First dielectric
34d Signal Via
34e Region
35 Second Board
35a Second Upper Pattern
35b Second Lower Pattern
35c Second Dielectric
35d Via
36a Third Upper Surface
36b Fourth Upper Surface
36c Third Lower Surface
37 Wiring
38 Conductive Adhesive Film
40 Second Capacitor
S1 Connecting Structure

1. A semiconductor device comprising:
a metal base;
a wall placed on the metal base, the wall providing an opening portion inside of the wall;
a lid placed on the wall;
a semiconductor die placed on the metal base, the semiconductor die being surrounded with the wall so as to be placed in the opening portion; and
at least one capacitor placed on a top surface of the wall and outside of the lid, wherein the capacitor includes a first terminal and a second terminal,
wherein the first terminal of the capacitor is electrically connected to the semiconductor die, and the second terminal of the capacitor is electrically connected to the metal base.

2. The semiconductor device according to claim 1, further comprising:
a first upper pattern placed between the capacitor and the top surface of the wall, the first upper pattern electrically connecting the first terminal of the capacitor with the semiconductor die; and
a second upper pattern placed on the top surface of the wall, the second upper pattern electrically connecting the second terminal of the capacitor with the metal base,
wherein the wall has a metal pattern on a region inside the wall, and
wherein the first upper pattern includes the metal pattern of the wall, and the metal pattern is electrically connected to a pad of the semiconductor die by a wiring,
wherein the pad of the semiconductor die is a drain pad of the semiconductor die.

3. The semiconductor device according to claim 2, further comprising:
a third upper pattern and a fourth upper pattern each placed on the wall,
wherein the third upper pattern is electrically connected to the first upper pattern,
wherein the fourth upper pattern is electrically connected to the second upper pattern and is electrically connected to the metal base via a via-hole.

4. The semiconductor device according to claim 1, further comprising:
a frame placed on a surface of the wall, the frame including a first upper pattern, a first lower pattern, and a dielectric sandwiched between the first upper pattern and the first lower pattern;
wherein the first upper pattern is electrically connected to the first terminal of the capacitor by a solder or electroconductive adhesive,
wherein the first lower pattern is electrically connected to the first upper pattern by a first via-hole through the dielectric and is electrically connected to the semiconductor die by a wiring.

5. The semiconductor device according to claim 4:
wherein the frame further includes a second upper pattern and a second lower pattern, the second upper pattern and the second lower pattern sandwiching the dielectric therebetween,
wherein the second upper pattern is electrically connected to the second terminal of the capacitor by a solder or electroconductive adhesive, and the second lower pattern is electrically connected to the second upper pattern by a second via-hole through the dielectric and is connected to the metal base.

6. The semiconductor device according to claim 1,
wherein the metal base is made of a high thermal conductivity material of 50 W/(m·K) or more,
wherein the wall is made of a glass-microfiber-reinforced resin or a fluorocarbon resin.

7. The semiconductor device according to claim 6,
wherein the high thermal conductivity material includes a copper or copper alloy.

8. The semiconductor device according to claim 1,
wherein the semiconductor die includes a substrate and a nitride semiconductor layer disposed on a surface of the substrate.

9. The semiconductor device according to claim 1, further comprising:
an impedance matching circuit placed on the metal base, the impedance matching circuit being surrounded with the wall and electrically connected to the semiconductor die;
wherein the lid covers the semiconductor die and the impedance matching circuit.

10. The semiconductor device according to claim 1,
wherein the at least one capacitor includes a first capacitor and a second capacitor,
wherein the first capacitor is placed on a first side portion of the wall, and the second capacitor is placed on a second side portion of the wall, opposite to the first side portion.

11. (canceled)

12. The semiconductor device according to claim 1,
wherein the semiconductor die includes a first semiconductor die and a second semiconductor die, and the opening portion includes a first opening portion and a second opening portion,
wherein the first semiconductor die is placed inside the first opening and the second semiconductor die is placed inside the second opening.

13. The semiconductor device according to claim 12, further comprising:
a first impedance matching circuit and a second impedance matching circuit,
wherein the lid includes a first lid and a second lid,
wherein the first lid covers the first semiconductor die and the first impedance matching circuit which are placed inside the first opening, and the second lid covers the second semiconductor die and the second impedance matching circuit which are placed inside the second opening.

14. The semiconductor device according to claim 12,
wherein the lid includes a first lid and a second lid, and the at least one capacitor includes a first capacitor, a second capacitor, a third capacitor and a fourth capacitor,
wherein the first capacitor and the second capacitor are located outside the first lid, and the third capacitor and the fourth capacitor are located outside of the second lid.

15. The semiconductor device according to claim 12, further comprising:
a first impedance matching circuit and a second impedance matching circuit,
wherein the lid covers the first semiconductor die, the second semiconductor die, the first impedance matching circuit, and the second impedance matching circuit.

16. The semiconductor device according to claim 12:
wherein the at least one capacitor includes a first capacitor and a second capacitor each placed on the wall,
wherein the first capacitor and the second capacitor are located outside the lid.
